(19) United States
(12) Patent Application Publication
(10) Pub. No.: US 2016/0218246 A1
(43) Pub. Date: Jul. 28, 2016

(54) EPITAXIAL TRANSPARENT CONDUCTIVE OXIDE ELECTRODES FOR GaN LEDS

(71) Applicant: Nthdegree Technologies Worldwide Inc., Tempe, AZ (US)

(72) Inventors: Bradley Steven Oraw, Chandler, AZ (US); Vera Nicholaevna Lockett, Phoenix, AZ (US)

(21) Appl. No.: 15/003,735

(22) Filed: Jan. 21, 2016

Related U.S. Application Data
(60) Provisional application No. 62/108,927, filed on Jan. 28, 2015.

(51) Int. Cl. H01L 33/42; H01L 33/06; H01L 33/00; H01L 33/62; H01L 33/46; H01L 33/32; H01L 25/075

(52) U.S. Cl. CPC H01L 33/42; H01L 33/32; H01L 33/06; H01L 25/0753; H01L 33/62; H01L 33/46; H01L 33/0075; H01L 2933/0016

(57) ABSTRACT

In one embodiment, a vertical LED die is formed by epitaxially growing over a sapphire substrate a transparent first conductive oxide layer, followed by an n-type GaN-based layer, followed by a GaN-based active layer, followed by a p-type GaN-based layer, followed by a transparent second conductive oxide layer. The transparent conductive oxide has a Wurtzite crystal structure that enables epitaxially growth of GaN-based layers over the conductive oxide. The substrate is then removed. The two conductive oxide layers may be top and bottom electrodes for the LED die. Since all layers are epitaxially grown, fabrication is simplified. The LED dies may be microscopic and printed as an ink over a bottom conductive layer that electrically contacts one of the transparent conductive oxide layers. The LED dies are sandwiched between the bottom conductive layer and a top conductive layer to form an ultra-thin flexible light sheet.

### CROSS-REFERENCE TO RELATED APPLICATIONS

This application claims priority from U.S. provisional application Ser. No. 62/108,927, filed Jan. 28, 2015, assigned to the present assignee and incorporated herein by reference.

### FIELD OF THE INVENTION

This invention relates to forming vertical light emitting diodes (LEDs) and, in particular, to forming GaN-based vertical LEDs having one or more epitaxially grown conductive oxide electrodes.

### BACKGROUND

GaN-based LEDs are sometimes formed to a have a deposited indium tin oxide (ITO) transparent conductive layer over the light emitting surface of the LED semiconductor layer, followed by depositing an opaque metal electrode. The metal electrode is patterned to form a center small dot, an array of dots, lines, an asterisk shape, or other shapes to allow most of the light to escape the top surface of the LED. The transparent conductive layer spreads the current from the metal electrode.

A transparent contact over the LED semiconductor layers is important for maximizing optical efficiency. There is usually a tradeoff between transparency and electrical performance. Contact potential and resistance between the contact material and the semiconductor determines the electrical performance. The electron and hole concentration in the semiconductors tends to be imbalanced such that either the p-type or n-type is more difficult to contact. Similarly, lower mobility in either the p-type or n-type requires low sheet resistance contact layers so that injected current remains uniform over large areas. Opaque metal contacts achieve low sheet resistance but at the cost of increased optical loss.

Transparent conductive oxides such as ITO are commonly used for transparent contacts to GaN. These contacts are physically deposited (not epitaxially grown) at a nominal thickness of 100 nm. Depending on the crystal structure of the resulting film, the resistance and transparency can be poor. Increasing the film thickness in excess of 1 um to reduce resistivity creates an optical loss that is too high for most applications.

Using more expensive vapor deposited films (not epitaxially grown) typically yields higher quality, higher transparency, and higher conductivity. The added cost tends to be restrictive for many applications, or the thickness must be limited to less than a practical minimum.

What is needed is an improved transparent contact for a GaN-based LED that has excellent transparency, low resistivity, and is inexpensive to manufacture.

### SUMMARY

Epitaxially grown, transparent conductive oxide contacts for GaN LEDs having high optical transmissivity and high electrical conductivity are described. The integration of forming epitaxially grown electrical contacts with the epitaxially grown LED semiconductor layers yields high material quality and also reduces device fabrication costs. Suitable transparent conductive oxide contacts include ZnO, MgO, CdO, MnO, CoO, and other transparent conductive oxides that have Wurtzite crystal structures that are similar to GaN, which enables the GaN-based LED layers to be epitaxially grown directly over the bottom conductive oxide layer, and enables the top conductive oxide layer to be epitaxially grown over the top GaN-based LED layer. Several integration and device fabrication methods are described.

In one embodiment, an electrical conductor, supplying power, directly contacts the transparent conductive oxide layer of the LED die. In another embodiment, a small metal bump contact may be formed over the transparent conductive oxide layer, where the bump is connected to the electrical conductor and the conductive oxide layer spreads the current. A metal mirror layer may also be used as an electrode contacting the conductive oxide layer, where light exits the opposite surface of the vertical LED or from the sides.

Nucleation layers can be used between a first layer of conductive oxide and the epitaxial growth substrate (e.g., sapphire). Intermediate contact layers, such as tunneling contacts between the conductive oxide layers and the p-type and n-type GaN layers are also described. Also, multiple novel selective growth techniques are described for forming isolated devices on the substrate during epitaxial growth, which also reduces device fabrication cost.

The resulting LED dies may be microscopic and printed as an ink over a bottom conductive layer. The LED dies are sandwiched between the bottom conductive layer and a top transparent conductive layer for connecting the printed LED dies in parallel. The conductive layers may directly contact the transparent oxide contacts or contact the bump or mirror layer described above.

### BRIEF DESCRIPTION OF THE DRAWINGS

FIG. 1 illustrates a stack of layers epitaxially grown over a growth substrate in an LED wafer, where individual LED dies are ultimately separated from the wafer.

FIG. 2 illustrates removal of the substrate from the structure of FIG. 1.

FIG. 3 illustrates the formation of a bump on the top surface of the structure of FIG. 2.

FIG. 4 illustrates the formation of a bump on the bottom surface of the structure of

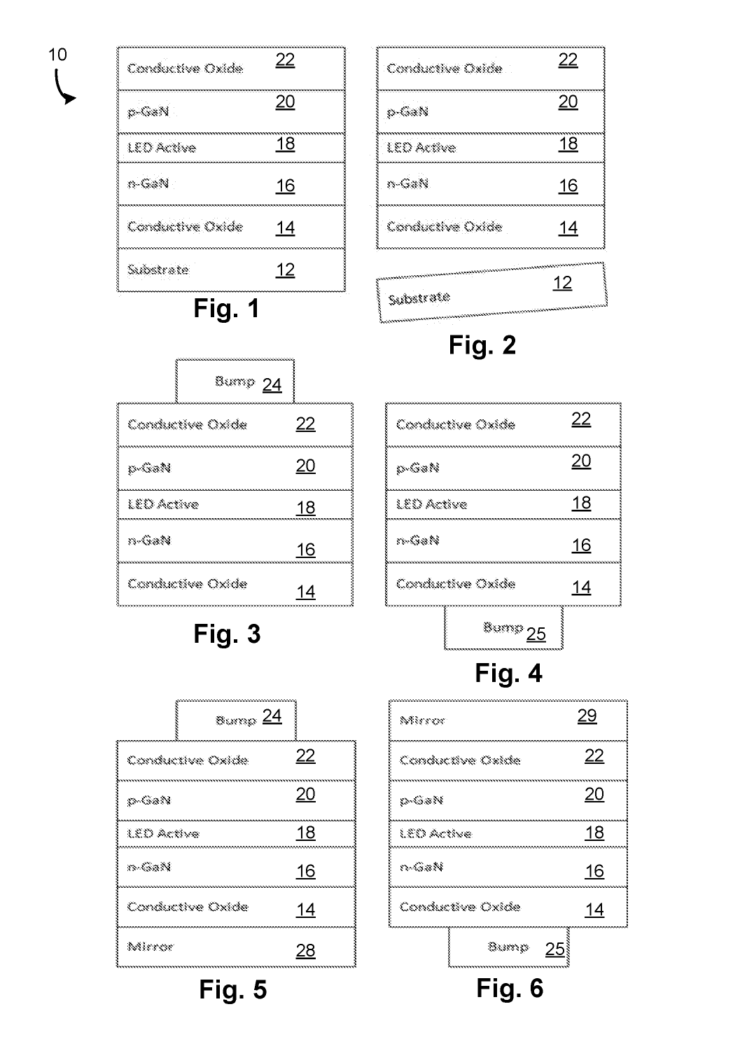

FIG. 2.

FIG. 5 illustrates the formation of a mirror layer on the bottom surface of the structure of FIG. 3.

FIG. 6 illustrates the formation of a mirror layer on the top surface of the structure of

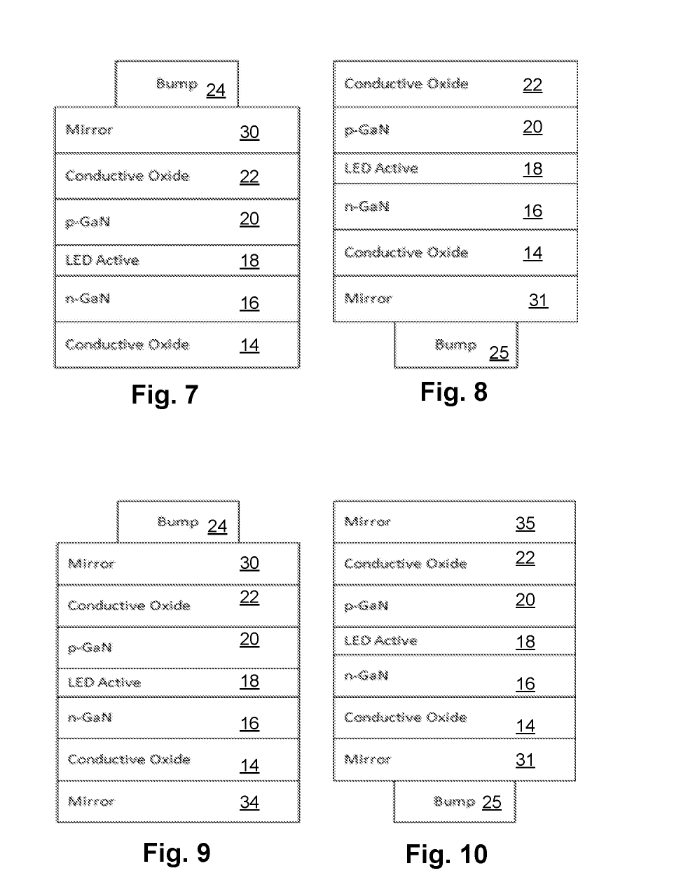

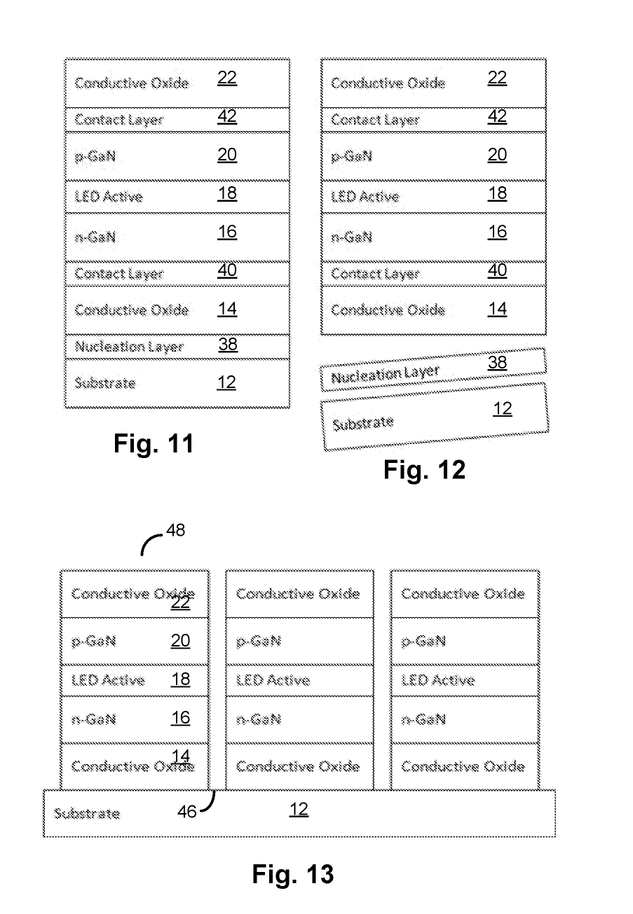

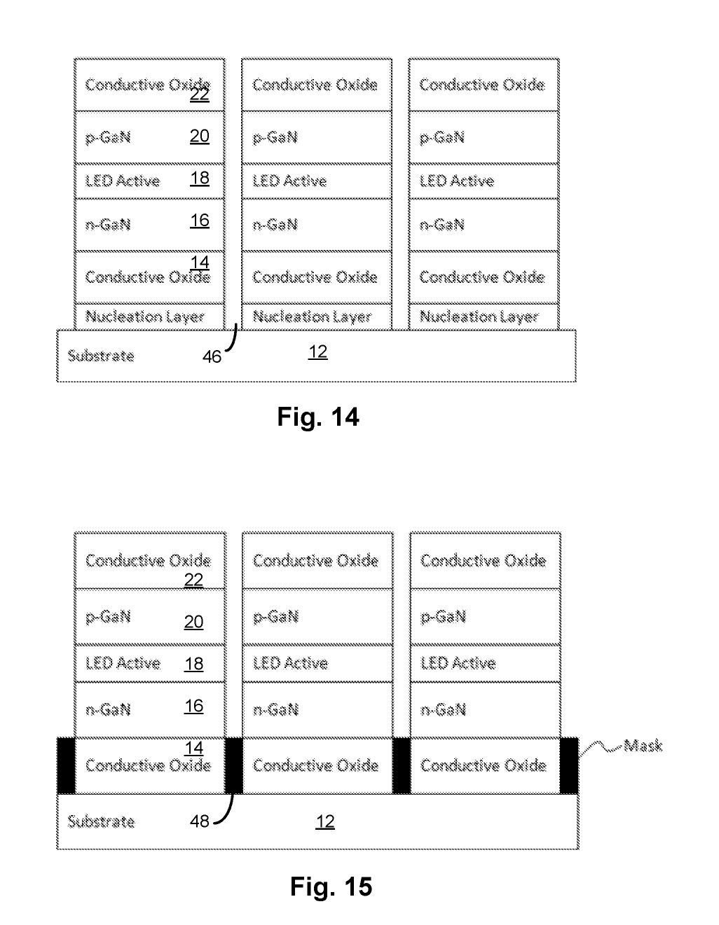

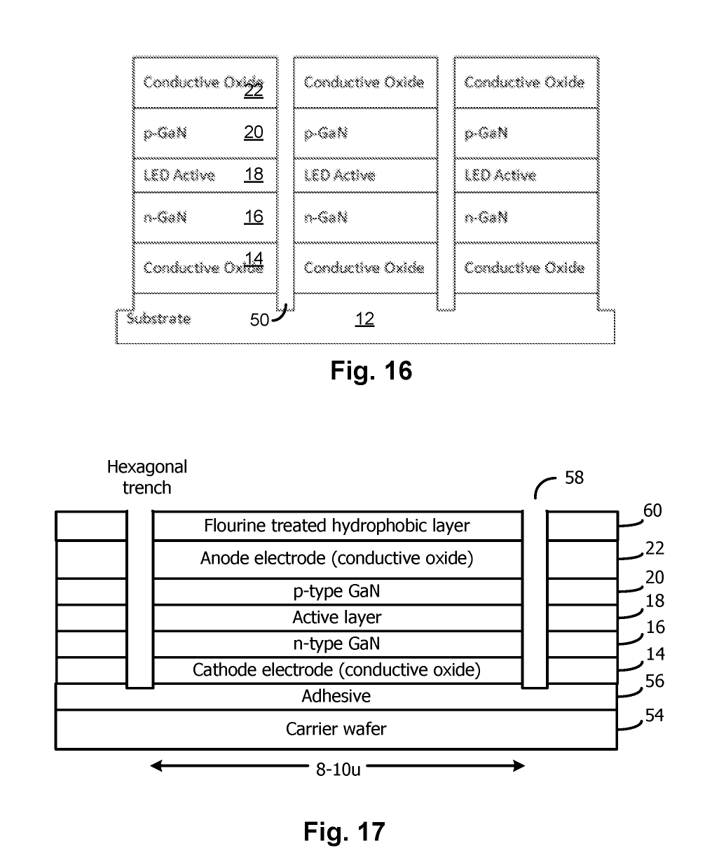

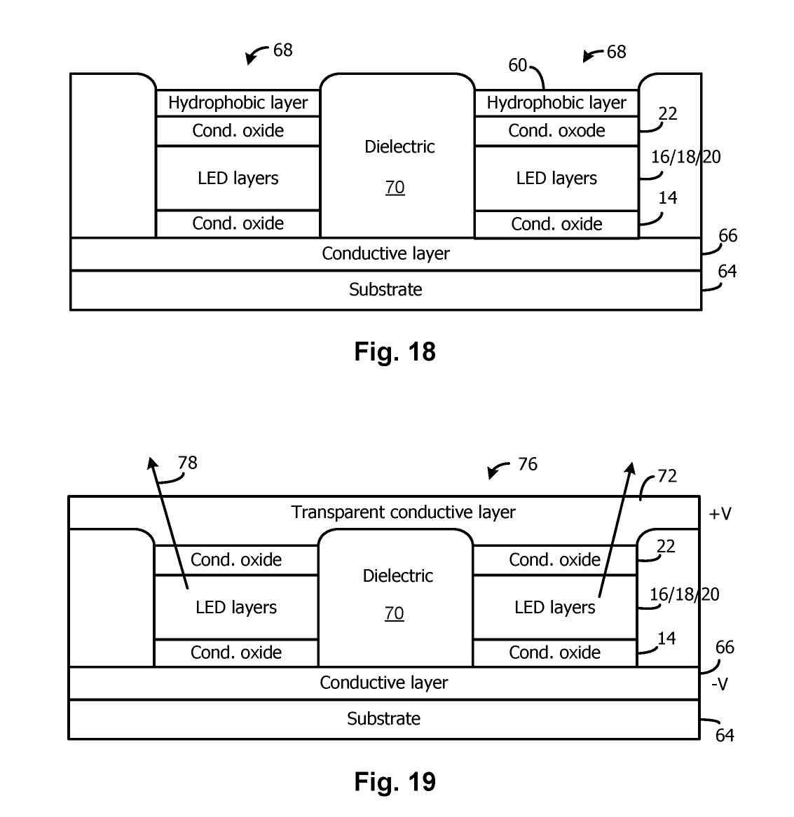

FIG. 4.

FIG. 7 illustrates the formation of a bump over a mirror layer on the top surface of the structure of FIG. 2.

FIG. 8 illustrates the formation of a bump over a mirror layer on the bottom surface of the structure of FIG. 2.

FIG. 9 illustrates the formation of another mirror layer on the bottom surface of the structure of FIG. 7.

FIG. 10 illustrates the formation of another mirror layer on the top surface of the structure of FIG. 8.

FIG. 11 illustrates the formation of a nucleation layer over the growth substrate and the addition of contact layers to the epitaxially grown stack of layers of FIG. 1

FIG. 12 illustrates the nucleation layer and substrate being removed from the structure of FIG. 11.

FIG. 13 illustrates the selective growth of epitaxial layers over a substrate.

FIG. 14 illustrates the selective growth of epitaxial layers over a substrate by patterning a nucleation layer.

FIG. 15 illustrates the selective growth of epitaxial layers over a substrate by patterning a mask layer.

FIG. 16 illustrates the selective growth of epitaxial layers over a substrate by forming trenches in the substrate.

FIG. 17 is a cross-sectional view of a portion of an LED wafer illustrating the epitaxial layers of FIG. 2 with a hydrophobic layer formed over the stack and trenches etched around each LED die area in the wafer.

FIG. 18 illustrates singulated LED dies that have been printed over a conductive layer and then partially encapsulated by a dielectric material.

FIG. 19 illustrates a completed LED light sheet where the LED dies are sandwiched between two conductive layers, where at least the top conductive layer is transparent.

Elements that are similar or identical in the various figures are labeled with the same numeral.

### DETAILED DESCRIPTION

FIG. 1 is a cross-sectional view of a portion of an LED wafer showing a vertical LED 10 in accordance with one embodiment of the invention, where transparent conductive oxide layers are epitaxially grown along with semiconductor GaN layers. Individual LED dies will later be separated from the wafer.

The starting substrate 12 may be any growth substrate that is suitable for growing GaN LED layers, such a sapphire, GaN, SiC, etc.

Over the substrate 12 is epitaxially grown a transparent conductive oxide layer 14, such as by chemical vapor deposition, annealed physical vapor deposition, solution deposition, and/or sol-gel techniques, so that the conductive oxide layer 14 has a crystalline structure compatible with growing GaN layers. Suitable transparent conductive oxides include ZnO, MgO, CdO, MnO, CoO, and other conductive oxides that have Wurtzite crystal structures (approximately a=3.2 A and c=5.2 A) that are similar to GaN. Epitaxially growing conductive oxides such as ZnO are known to those skilled in the art. For example, see Structural characterization of two-step growth of epitaxial ZnO films on sapphire substrates at low temperatures, by P Pant et al., JOURNAL OF PHYSICS D: APPLIED PHYSICS 42 (2009) 105409 (8pp), incorporated herein by reference.

The oxide layer 14 may range from 10 nm to 10 um.

ZnO is particularly unique since its 3.3 eV bandgap is similar to the 3.4 eV bandgap of GaN. ZnO is intrinsically an n-type semiconductor. Doped and alloyed oxides are also possible. Al, In, Ga, Sn are some dopants of ZnO. Mg, Mn, Co can be alloyed with ZnO. Electronic and magnetic properties of doped and alloyed oxides can be selected for a given application.

The epitaxial grown, crystalline conductive oxides in this embodiment can be used as optically transmissive electrical contacts to both p-type and n-type GaN. Such contacts may also be electrodes if they serve as the outer layer of the LED die that is connected to a conductor of power to the LED die.

An n-type GaN layer 16 is then epitaxially grown (e.g., using MOCVD or MBE) on this first crystalline conductive oxide layer 14, followed by a GaN-based active layer 18 with quantum wells, and a p-type GaN layer 20. The GaN epitaxy stack is typical of a hetrojunction LED. Each of the GaN layers 16, 18, and 20 may comprise multiple sub-layers. For example, ramped doping levels may be in sub-layers of the n-type GaN layer 16 to reduce stress caused by any lattice mismatch.

A second conductive oxide layer 22 is epitaxially grown on the GaN LED stack, which may be the same as the first conductive oxide layer 14. The conductive oxide layer 14 provides an electrical contact to the n-type GaN layer 16, and the conductive oxide layer 22 provides an electrical contact to the p-type GaN layer 20.

As shown in FIG. 2, the growth substrate 12 is then removed to access the bottom conductive oxide layer 14 for electrical contact. Laser lift-off or etching (e.g., grinding) can be used to remove the substrate 12.

An advantage of epitaxially-grown contacts for the p-type side and the n-type side is a simpler device process. Since the epitaxial stack already includes electrical contacts, contact deposition, using a very different method such as spraying or PVD, is not required in a subsequent device fabrication process.

The LED wafer may then be singulated into microscopic LED dies and the LED dies placed into an ink solution for printing. Details of the printing process are described later.

A bump may be formed on either end (prior to singulation) in order for the printing process to orient the LED dies in a particular way. FIG. 3 shows a bump 24, while FIG. 4 shows a bump 25. Standard photolithographic and deposition processes may be used to form the bump 24/25 after the epitaxial layers have been grown. The bump 24/25 causes the printed LED dies to orient with the bump 24/25 upward as the LED dies drift downward through the ink solution after printing. The flexibility of placing the bump 24/25 on either the p-type or n-type side is an advantage for selecting the polarity of the LED die with regard to its orientation.

The bump 24/25 material can be electrically conductive (e.g., metal) or insulating, or optically transmissive (e.g., ITO) or opaque, depending on the application requirements. If the bump 24/25 is conductive, after the LED dies are printed over a bottom first conductive layer, the metal bump can be contacted by a printed top second conductive layer to supply power to the LED dies. If no bump is used, the top second conductive layer directly contacts the conductive oxide layer 14 or 22. The top and/or bottom conductive layers can be transparent to allow light to pass through. Light can exit the LED die from either or both surfaces (and also from its sides), and an opaque bump 24/25 reduces the light emitted from the bump-side. A smaller opaque bump 24/25 increases light extraction from the bump side.

If no bump is used, the LED dies may randomly orient on the bottom first conductive layer when printing, so that approximately 50% will be oriented up and the rest orientated down. Such an array of LED dies connected in parallel between the first and second conductive layers may be driven with an AC voltage so that all the LED dies are energized. If the bottom first conductive layer is reflective (e.g., an aluminum layer), all light will exit upward.

As shown in FIGS. 5 and 6, a mirror layer 28 or 29 can be deposited on the side of the epitaxial stack opposite the bump side. The mirror layer 28/29 provides internal reflection such that the light emission from the LED dies is predominantly injected into one hemisphere. One-sided emission is advantageous in certain applications. If the mirror layer 28/29 is made sufficiently heavy, the LED dies will orient with the mirror layer 28/29 down when printing, which may obviate the need for the bump 24/25 to be used for orientation.

Alternatively, as shown in FIGS. 7 and 8, the bump 24/25 and mirror layers 30/31 can be placed on the same side of the LED die. This configuration is advantageous in some applications, since the bump is not in the optical path. The bump 24/25 can be placed on either the p-type or n-type side of the device.

As shown in FIGS. 9 and 10, two mirror layers 30/34 and 31/35 can also be useful in some applications. A mirror layer 30/34/31/35 is deposited on both conductive oxide layer surfaces. This configuration only allows light emission from the sidewalls of the LED dies, which is advantageous for guided wave applications like backlighting. For example, if all the LED dies in a thin light sheet only emitted light from their sides and were sandwiched between two reflective conductor layers connecting the LED dies in parallel, one thin edge of the LED light sheet can emit all the generated light into the edge of a light guide for use as a backlight. The injected light would be substantially uniform since the LED light sheet mixes the light.

As shown in FIG. 11, additional layers might be desired in some applications. A nucleation layer 38, such as GaN, AN, TiO2, MgO, CrN, Cr2O3, and other nitrides or oxides, might be necessary to initiate epitaxial growth on certain substrates such as sapphire, silicon, silicon carbide, MgO, TiO2, and similar materials. The nucleation layer 38 can be grown using low cost solution deposition or sol-gel techniques.

A conductive contact layer 40, such as heavily n-doped GaN, between the conductive oxide layer 14 and the n-GaN layer 16 might be necessary. Similarly a contact layer 42 between the conductive oxide layer 22 and the p-GaN layer 20 might be necessary. For example, assume the conductive oxide layer 22 were ZnO. Since ZnO is intrinsically n-type, a hetrojunction would be created between the n-ZnO and the p-GaN layer 20. Since p-type dopants for ZnO are not easily added, n-type ZnO is only available presently. A tunneling contact layer 42 between the n-ZnO and the p-GaN layer 20 is an effective solution. Thin layers (1-50 A) of high work function metals such as Au, Ni, Pt, and Pd can be used to tunnel between the p-GaN layer 20 and the n-ZnO. Thin layers (1-50 A) of heavily doped p-type or n-type of strained semiconductor such as InGaN can also be an effective tunneling contact layer. Thin layers (1-50 A) of heavily doped p-type or n-type conductive oxide such as n+ZnO could also be an effect tunneling contact layer. A thin (1-50 A) layer of insulating material could also be an effective tunneling contact layer.

The removal of the nucleation layer 38, shown in FIG. 12, is necessary in some applications to expose the conductive oxide layer 14 surface for supplying power to the LED die. The nucleation layer 38 can be removed using an etching process or could be removed with the substrate 12 during certain substrate removal processes.

The LED wafer is then singulated to define the individual LED dies.

In another embodiment, singulation is not performed on the epitaxial layers to define the individual LED dies. As shown in FIG. 13, the LED die portions of the LED wafer may be defined by patterning non-growth areas 46 on the substrate 12. The selective growth areas promote growth in the desired patterned areas and inhibit growth in the remaining areas. Using selective growth, isolated LED areas 48 could be created epitaxially. By just removing the substrate 12, the individual LED dies are created. The top surface of the LED wafer may first be affixed to a releasable adhesive layer for mechanically supporting the wafer during the substrate 12 removal process. In conventional LED wafer processing, the LED dies are singulated during the fabrication processing by etching, sawing, or scribing through the epitaxial stack. Isolating devices during epitaxial growth, as shown in FIG. 13, obviates such mechanical processes and reduces the cost of device fabrication.

One method for selective growth is to pattern the nucleation layer 38, as shown in FIG. 14. The nucleation layer 38 could be grown then subsequently etched, using a conventional photolithographic process, to define the selected growth areas. The conductive oxide layer 14 is grown on the selected nucleation layer 38 areas. Growth would be inhibited in the unselected areas 46. The gap between adjacent selected areas should be proportional to the total thickness of the epitaxial stack, which will prevent coalescent 3D growth that would bridge the separate areas.

Another method of selective growth, shown in FIG. 15, is using a patterned masking layer 48 over the substrate 12. The mask material is chosen to inhibit epitaxial growth, such as an amorphous oxide layer or photoresist layer. After completing the stack and removing the growth substrate 12, the masking layer 48 can be selectively removed by etching, dissolving, or other means.

Another method of selective growth, shown in FIG. 16, uses an etched substrate 12. The substrate 12 has etched trenches 50 which inhibit coalescent 3D epitaxial growth between adjacent growth mesas. The mesa height and trench width are chosen to ensure two discontinuous growth planes which guarantees isolated devices.

Epitaxial growth of conductive oxides for n-type and p-type GaN contacts has been described. High material quality resulting in higher optical transmissivity and higher conductivity can be achieved by epitaxial oxide growth. Low cost epitaxial growth techniques such as solution deposition and/or sol-gel techniques are possible. The integration of the electrical contacts during the epitaxial growth reduces device fabrication costs. The conductive oxide layers are compatible with other device layers such as bumps and mirrors. Nucleation layers can be used to better interface conductive oxide growth on particular substrates. Intermediate contact layers, such as tunneling contact layers, can be used to better interface the conductive oxides with the p-type and n-type GaN. Several other methods for selective epitaxial growth have also been proposed. The advantages of the selective growth embodiment include device isolation during growth, which reduces device fabrication cost.

FIG. 17-19 are directed to techniques that may be used to print the microscopic LED dies and connect printed LED dies in parallel to form a very thin and flexible LED light sheet.

FIG. 17 illustrates a very small portion of an LED wafer prior to singulation. The LEDs may have a hexagonal shape or any other suitable shape.

The LED epitaxial layers may be the same as shown in FIG. 2. The growth substrate has been removed and replaced with a carrier wafer 54, such as glass or silicon, affixed to the epitaxial layers with a releasable adhesive layer 56.

Using a mask, trenches 58 are etched through the layers down to the adhesive layer 56 to define the boundaries of the LED dies on the wafer. Alternatively, the selective growth techniques described above may be used to isolate the LEDs. The LED dies may have a width of about 8-10 microns. The width is selected to maximize the efficiency of the microscopic LED while enabling high reliability fabrication of the LED dies. Larger or smaller LED sizes can be used. The thickness of the LEDs is on the order of about 7 microns.

The conductive oxide layer 22 (serving as an anode electrode) is then treated with a fluorine process to create a thin hydrophobic layer 60. This may be done in a CVD process to form a fluorocarbon layer or fluoropolymer layer, or any other suitable hydrophobic layer, or may simply be done by depositing a thin layer of a commercially obtained fluorosurfactant material that is typically used for creating water repellant surfaces. Depositing the hydrophobic layer 60 may be done using printing, spraying, or other suitable process. Forming a super-hydrophobic surface is preferred. This process may be performed before or after the trenches 58 are formed.

The resulting LED dies are singulated by either dissolving the adhesive layer 56 by immersing the wafer in a solvent or by etching or grinding off the carrier wafer 54 until the trenches 58 are reached.

The singulation may be performed in an aqueous medium so the LED dies become uniformly dispersed in the medium to form an LED ink. The LED ink may include a viscosity-modifying polymer resin to form an LED ink suitable for printing using screen printing, flexographic printing, gravure printing, or any other suitable deposition method, including spraying, etc. The ink is to be printed in a thin layer so the LED dies form a monolayer of a predictable density and are randomly but generally uniformly distributed on the printed surface. In one embodiment, the LED dies are printed so that there is an average of about one LED die per square millimeter.

The printing process and light sheet formation process will now be described with respect to FIGS. 18 and 19.

In FIG. 18, a thin, flexible substrate 64, such as a PET film on a roll, is provided. Mylar, PMMA, aluminum, or other suitable films may be used instead. The substrate 64 may be on the order of a few mils.

The substrate 64 on the roll may be provided with a conductive layer 66, or the conductive layer 66 may be deposited on the substrate 64, such as by printing, spraying, etc., as the substrate 64 is being unrolled in a roll-to-roll process. The conductive layer 66 may be a reflective metal or may be a transparent conductor such as ITO or sintered silver nanowires.

The LED dies 68 are then printed over the conductive layer 66 to form a monolayer of LED dies 68, and the ink is then cured, such as by lamps, to evaporate the aqueous medium. If the LED dies 68 are properly oriented, the conductive oxide layer 14 (serving as a cathode electrode) will electrically contact the conductive layer 66. Any LED dies 68 that are not properly oriented will not affect the operation of the light sheet. The semiconductor LED layers are the combination of the n-type GaN layer 14, the active layer 16, and the p-type GaN layer 20. In one embodiment, the shapes of the LED dies 68 are designed to properly orient the LED dies 68 on the conductive layer 66.

A liquid hydrophilic dielectric material 70 is deposited over the LED dies 68 and the conductive layer 66 to a thickness about equal to the tops of the LED dies 68. The dielectric material 70 may be transparent or contains light-diffusing particles. Hydrophilic dielectric materials are commercially available and generally have the de-wetting characteristics of water relative to a hydrophobic surface. Deposition may be by printing, spraying, etc.

As shown in FIG. 18, the dielectric material 70 pulls off the top surfaces of the LED dies 68 by surface tension to expose the entire hydrophobic layer 60. The dielectric material 70 is then cured.

In FIG. 19, the hydrophobic layer 60 is neutralized or removed, such as by a brief blanket etch or by dissolving, to expose the underlying epitaxially-grown conductive oxide layer 22. In one embodiment, the thin hydrophobic layer 60 is naturally removed or neutralized after a time or during the curing of the dielectric material 70 by heat or UV.

A top conductor layer 72 is then deposited over the conductive oxide layer 22 and cured to electrically connect all the LED dies 68 in parallel. In one embodiment, the conductive layer 72 is a transparent conductor such as ITO or sintered silver nanowires.

A protective layer (not shown) may then be deposited over the conductive layer 72. A phosphor layer may be deposited to achieve any color. In one embodiment, the phosphor is YAG (yellow) and some blue LED light leaks through the phosphor to create white light.

The resulting light sheet 76 may be any size. For large sizes, thin metal bus lines may create a grid pattern to better distribute the driving voltage. Edges of the light sheet 76 may terminate in robust metal electrodes for connection to a driving voltage. FIG. 19 illustrates a driving voltage V− and V+ being applied to the conductive layers 66 and 72 to cause the LED dies 68 to emit light 78 that exits through the top surface of the light sheet 76.

This technique can also be used for forming an addressable array of printed LEDs. In such an embodiment, the LEDs are printed in an array of small groups as addressable pixels, and addressable XY conductors are energized to energize a pixel at the intersection of the energized conductors.

This technique can also be employed for creating more efficient micro-components that are printed and contacted by conductor layers, such as non-LED silicon diodes, 3-terminal transistors, etc.

The light sheet 76 can be used for general illumination, displays, backlights, indicator lights, etc.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A light emitting structure comprising:
a first vertical light emitting diode (LED) die comprising:
a transparent first conductive oxide layer epitaxially grown over a growth substrate;
a first GaN-based layer epitaxially grown over the first conductive oxide layer;
a GaN-based active layer epitaxially grown over the first GaN-based layer;
a second GaN-based layer epitaxially grown over the active layer; and
a transparent second conductive oxide layer epitaxially grown over the second GaN-based layer.

2. The structure of claim 1 wherein the first GaN-based layer comprises an n-type GaN-based layer, and the second GaN-based layer comprises a p-type GaN-based layer.

3. The structure of claim 1 wherein the first conductive oxide layer and the second conductive oxide layer have a Wurtzite crystal structure.

4. The structure of claim 1 wherein the first conductive oxide layer and the second conductive oxide layer comprise one of ZnO, MgO, CdO, MnO, or CoO.

5. The structure of claim 1 wherein the first GaN-based layer comprises a plurality of sub-layers.

6. The structure of claim 1 wherein the second GaN-based layer comprises a plurality of sub-layers.

7. The structure of claim 1 further comprising a first conductive layer electrically contacting the first conductive oxide layer for supplying a first voltage to the first conductive oxide layer, and a second conductive layer electrically contacting the second conductive oxide layer for supplying a second voltage to the second conductive oxide layer for energizing the first LED die.

8. The structure of claim 7 further comprising a plurality of LED dies substantially identical to the first LED die also electrically contacted by the first conductive layer and the second conductive layer for connecting the plurality of LED dies and the first LED die in parallel.

9. The structure of claim 7 wherein the first conductive layer directly contacts the first conductive oxide layer.

10. The structure of claim 7 wherein the second conductive layer directly contacts the second conductive oxide layer.

11. The structure of claim 10 wherein the second conductive layer is transparent.

12. The structure of claim 7 wherein the first LED die is microscopic and printed as an ink over the first conductive layer.

13. The structure of claim 1 further comprising a bump feature formed over a portion of the second conductive oxide layer.

14. The structure of claim 13 wherein the bump feature is conductive.

15. The structure of claim 13 wherein the bump feature orients the first LED die upward when printing the first LED die as an ink.

16. The structure of claim 1 further comprising a bump feature formed over a portion of the first conductive oxide layer.

17. The structure of claim 16 wherein the bump feature is conductive.

18. The structure of claim 16 wherein the bump feature orients the first LED die upward when printing the first LED die as an ink.

19. The structure of claim 1 further comprising a conductive mirror layer abutting one of the first conductive oxide layer and the second conductive oxide layer.

20. The structure of claim 1 further comprising the growth substrate, wherein the substrate is treated such that the first conductive oxide layer, the first GaN-based layer, the GaN-based active layer, the second GaN-based layer, and the second conductive oxide layer are only epitaxially grown over selected areas of the substrate.

21. The structure of claim 20 further comprising a patterned nucleation layer over the substrate, wherein the first conductive oxide layer, the first GaN-based layer, the GaN-based active layer, the second GaN-based layer, and the second conductive oxide layer are only epitaxially grown over areas of the substrate having the nucleation layer.

22. The structure of claim 20 further comprising a patterned mask layer over the substrate, wherein the first conductive oxide layer, the first GaN-based layer, the GaN-based active layer, the second GaN-based layer, and the second conductive oxide layer are only epitaxially grown over areas of the substrate where there is no mask layer.

23. The structure of claim 20 wherein the substrate has trenches formed in it, wherein the first conductive oxide layer, the first GaN-based layer, the GaN-based active layer, the second GaN-based layer, and the second conductive oxide layer are only epitaxially grown over areas of the substrate that are not in a trench.

24. The structure of claim 1 further comprising a tunneling contact layer between the second GaN-based layer and the transparent second conductive oxide layer.

25. The structure of claim 24 wherein the second GaN-based layer is p-type and the transparent second conductive oxide layer comprises ZnO.

26. A method of forming a light emitting structure comprising:
forming a first vertical light emitting diode (LED) die comprising:
epitaxially growing a transparent first conductive oxide layer over a growth substrate;
epitaxially growing a first GaN-based layer over the first conductive oxide layer;
epitaxially growing a GaN-based active layer over the first GaN-based layer;
epitaxially growing a second GaN-based layer over the active layer; and
epitaxially growing a transparent second conductive oxide layer over the second GaN-based layer.
